(19) United States
(12) Patent Application Publication
(10) Pub. No.: US 2006/0001926 A1
(43) Pub. Date: Jan. 5, 2006

(54) Method for optimizing a digital document including special colors

(76) Inventors: Martin Beyer, Bergkamen (DE); Francis Lamy, Wollerau (CH); Thomas Senn, Dielsdorf (CH)

Correspondence Address: MCCARTER & ENGLISH LLP;CITYPLACE I, 185 ASYLUM STREET, HARTFORD, CT, 06103, US

(21) Appl. No.: 11/121,441

(22) Filed: May 4, 2005

(30) Foreign Application Priority Data
May 4, 2004 (EP) 04010672.6

(51) Int. Cl. G03F 3/08; G06F 15/00

(52) U.S. Cl. 358/518; 358/1.9

(57) ABSTRACT

A method for optimizing a digital document having special colors, the digital document serving as an original in a reproduction process, especially a printing process, the method includes storing data corresponding to special colors, with the goal of a true-color reproduction in the reproduction process; examining the digital document for the presence of special colors; and replacing any of the special colors present in the document by replacement colors with standard color definitions using the stored data. The definitions for the replacement colors can be manually input, selected from a color library, or determined by color measurement on a physical color reference.

### BACKGROUND OF THE INVENTION

The invention relates to a method for optimizing a digital document including special colors, the digital document serves as an original in a reproduction process, especially a printing process. The method includes storing data on special colors, with the goal of a true-color reproduction in this reproduction process.

Processing in the graphics industry is carried out to an ever increasing degree on a digital basis. For a conventional printing order, the designer generates an original by way of powerful software applications as a digital document and transmits the digital document through a suitable transport medium to the reprographer. The reprographer then feeds the document to a color separation processor (e.g., a raster image processor (RIP), which automatically calculates therefrom the color raster extracts for the later printing process. The known portable document format (PDF) or the post script format (PS-format) is commonly used for the documents, but other digital formats can also be used which can be handled by the color separation processor used.

It is a problem when a designer uses special colors in the original which are not defined by the coordinate values of the commonly used color spaces (e.g., Lab or CMYK). CIE L a b (CIELAB) is the most complete color model used conventionally to describe all the colors visible to the human eye. LAB is designed to be device independent and is used by such software as Photoshop as a intermediary step when converting from one color space to another. LAB is based on the discovery that somewhere between the optical nerve and the brain, retinal color stimuli are translated into distinctions between light and dark, red and green, and blue and yellow. Lab images use three components to represent color, which are three channel images containing 24 (8×3) bits per pixel.

In contrast, CMYK (Cyan-Magenta-Yellow-blacK) is a “subtractive” color system used in printing where inks or pigments are mixed. CMYK images consist of the four colors (e.g., cyan, magenta, yellow and black) used to print color separations. They are four-channel images, containing 32 (8×4) bits per pixel.

The color separation processor normally can not process or correctly process such special colors, ornamental colors or spot colors. Therefore, the final printing result is most likely unsatisfactory as to color.

### SUMMARY OF THE INVENTION

The above described difficulty is now overcome by the present invention. The invention provides a basis for the production of reproduction results, which are satisfactory as to color including those original digital documents having special colors. Although the reproduction is understood to include a printing process in an exemplary embodiment, the reproduction can also include any other output process, including for example, the reproduction on a screen.

An aspect underlying the invention is now provided by a method for optimization of a digital document serving as an original in a reproduction process, especially a printing process and includes storing data corresponding to special colors, with the goal of a true-color reproduction in the reproduction process. In an exemplary embodiment, the digital document is examined for the presence of special colors and the special colors in the document are replaced by replacement colors with standard color definitions using the stored data.

According to the main aspect of the invention, all special colors present in the original digital document are replaced by suitable standard color definitions and the reproduction documents are correspondingly modified. This can be carried out by manual input, selection from a color library or by scanning. The replacement colors can thereby be defined in the document, for example, as coordinates of the Lab-color space or, if the profile of the reproduction process used is known, by coordinates of the reproduction color space.

This application claims priority to Application No. 04 010 672.6, filed May 5, 2004, in the European Patent Office, the contents of which are incorporated by reference in their entirety.

### BRIEF DESCRIPTION OF THE FIGURES

The invention will be further described in the following disclosure in conjunction with the drawings enumerated below.

FIG. 1 is a general overview schematic of a process flow of a printing order;

FIG. 2 is a flow diagram of an exemplary embodiment of the process in accordance with the invention; and

FIG. 3 is a flow diagram of one of the blocks of the process of FIG. 2.

### DETAILED DESCRIPTION OF A PREFERRED EMBODIMENT

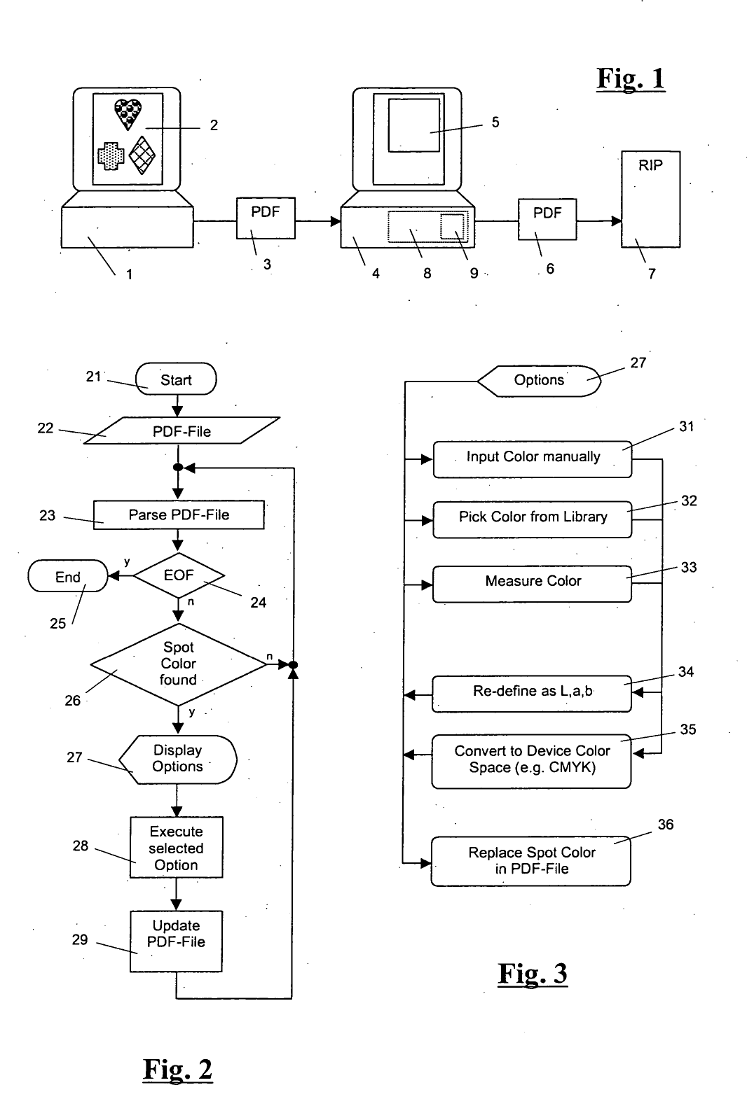

As shown in FIG. 1, the designer generates a print original 2 on a computer 1 by way of a suitable, ideally color management enabled software application (one of the common desktop publishing programs, such as, for example, “Express” by Quark). After the print original 2 is completed, it is saved as a digital document 3, for example in PDF format. The print original 2 can include in a generally known manner both graphic elements as well as text elements. Special colors are selected for several elements of the printing original. If the software application does not support the saving of the digital document 3 in PDF format, the conversion into this format can of course also be carried out by way of a separate application designed therefore, for example Adobe Acrobat program commercially available from Adobe Systems Incorporated.

The digital document 3 is then transmitted to the repro-establishment (for example, by e-mail or by another digital transport medium) and is analyzed and possibly modified in accordance with the invention in a computer 4 in a manner to be further described. Information and interactive options 5 are thereby illustrated and offered on the screen of the computer 4. The optionally modified digital document 6 is then fed to a color separation processor raster image processor (RIP) 7, which calculates in a generally known manner the color extracts required for the later printing process.

A known software application 8 runs on the computer 4 which can read the digital document 3. An Adobe Acrobat PDF reader application is typically used in an exemplary embodiment. In addition, a special software application 9 is installed on the computer 4 which carries out the process steps in accordance with the invention described in the following disclosure. This special application 9 is preferably implemented as a supplement (a so called plug-in) to the PDF reader application 8. The programming for the realization of the processing steps and incorporation into the PDF reader application 8 is within the range of capabilities of the average person skilled in the art and is not a subject of the invention.

After the digital document 3 is loaded into the PDF reader application 8, the special application 9 is either automatically or manually started. The processing steps in accordance with the invention described in the following and schematically illustrated in FIGS. 2 and 3 are thereby carried out.

After the program start (Block 21), the loaded digital document 3 (Block 22) is read out section by section (Block 23) in a known manner. The digital document is investigated at each section to determine whether the document includes the description of a special color (Block 26). If no special color is found in the section, the next section is analyzed. The whole is repeated until the end of the document 3 is reached (Block 24) and the process ends (Block 25).

When a special color is found (Block 26), this is indicated on the screen of computer 4 and options for further processing are offered (Block 27). These options generally correspond to a new definition of the special color found. Details in relation hereto are described further below. When the user selects at least one of the offered options, the computer 4 then carries out the associated tasks with this selection and the special color is newly defined in this manner (Block 28). Finally, the new definition of the special color is written into the digital document 3 and the digital document is updated (Block 29). These steps are repeated until all of the special colors are found and replaced by new definitions.

It is understood by one of ordinary skill in the pertinent art that the process may alternatively first determine all of the special colors present and thereafter carry out each of their respective new definitions.

A selection of the options 27 is schematically illustrated in detail in FIG. 3. The simplest option of obtaining the definition of the special color is carried out by manual input of corresponding color values (Block 31). For this, the special application 9 provides corresponding input windows in a known manner and preferably also graphically illustrates the input color on the monitor. The replacement color so defined can also be stored in a color data library for further use (see also below).

A further option includes selecting a replacement color selected from a colordata library (Block 32) which is stored in (or externally input into) the computer 4. For this, the colors included in the library are therefore, for example, graphically illustrated by the special application 9 in a selection menu. A library present in the known color exchange format (CxF-Format) is preferably used as the color data library.

It can be provided as a further option that the replacement colors for the special colors are determined by color measurement at a physical color reference (Block 33). The color measurement can be carried out by way of a color measurement device, such as for example the “EyeOne” color spectrophotometer of Gretag-Macbeth, the assignee of the present application, connected to the computer 4, whereby this step can be supported in a known manner by the special application 9.

The respective replacement colors are normally defined by coordinate values in the Lab color space (Block 34). Alternatively, the definition can however also be carried out in the color space of the later printing process, normally CMYK (Block 35). However, in order for that to occur, the color transfer characteristics (the color profile) of the printing process (for example reproduction processes in general) are required to be known.

Finally, the replacement colors or new definitions of all special colors included in the document are written into the document and the updated document is again saved in the original format (Block 36). This is carried out in a known manner according to the same syntax rules used while saving the original document. A person of ordinary skill in the pertinent art does not require any further description in relation thereto.

It is understood that the special application 9 can be expanded at will in a known manner in order to design the required actions of the user to be as easy, intuitive and clear as possible to the user.

Although the present disclosure has been provided with reference to exemplary embodiments thereof, the present disclosure is not to be limited thereto. Rather, modifications, enhancements and/or variations to the disclosed devices, systems and features are contemplated, and such modifications, enhancements and/or variations will not depart from the spirit or scope of the present disclosure.

What is claimed is:

1. A method for the optimization of a digital document serving as an original in a reproduction process, the method comprising:
storing data corresponding to a respective special color of a plurality of special colors, the data corresponding with a true-color reproduction of the plurality of special colors in the reproduction process;
examining the digital document is examining the digital document for the presence of any special colors; and
replacing any of the special colors present with corresponding replacement colors having standard color definitions using the stored data.

2. The method according to claim 1, wherein at least one of the replacement colors is defined by manual input.

3. The method according to claim 1, wherein only the special colors in the digital document are replaced by replacement colors having standard color definitions.

4. The method according to claim 1, wherein at least one of the special colors is defined by selection from a color data library.

5. The method according to claim 1, wherein at least one of the replacement colors is defined by color measurement on a physical color reference.

6. The method according to claim 1, wherein at least one of the replacements colors is defined by coordinate values in the Lab color space.

7. The method according to claim 1, wherein at least one of the replacement colors is defined by coordinate values in the color space of the reproduction process.

8. The method according to claim 1, wherein the digital document is present in PDF or PS format.

9. The method according to claim 1, wherein the digital document is saved after replacement of the special colors in a same digital format as the original digital document.

10. The method according to claim 1, wherein the reproduction process includes a printing process.

11. The method according to claim 1, wherein the reproduction process includes an image projection process on an image screen.
